(19) United States
(12) Patent Application Publication
(10) Pub. No.: US 2012/0293248 A1
(43) Pub. Date: Nov. 22, 2012

(54) ACTIVE AND CONFIGURABLE FILTER DEVICE

(75) Inventors: Chun-Liang CHEN, Tainan City (TW); Hui-Chun HSU, Bade City (TW)

(73) Assignee: Sunplus Technology Co., Ltd., Hsinchu (TW)

(21) Appl. No.: 13/426,665

(22) Filed: Mar. 22, 2012

(30) Foreign Application Priority Data
May 20, 2011 (TW) 100117702

(51) Int. Cl. H03B 1/00

(52) U.S. Cl. 327/553

(57) ABSTRACT

An active and configurable filter device includes a first filter with a first quality factor, a second filter with a second quality factor and a third filter with a third quality factor. The first filter defines a bandwidth and central frequency of the filter device. The second filter is connected to the first filter for using the spectrums of the first filter and second filter to define a lower bound frequency and sharpness of the bandwidth of the filter device. The third filter is connected to the second filter for using the spectrums of the first filter and third filter to define an upper bound frequency and sharpness of the bandwidth of the filter device. The first quality factor is an adjustable value in a range of 5 to 15, and the second and the third quality factors are each an adjustable value greater than 15.

### CROSS REFERENCE TO RELATED APPLICATION

This application claims the benefits of the Taiwan Patent Application Serial Number 100117702, filed on May 20, 2011, the subject matter of which is incorporated herein by reference.

### BACKGROUND OF THE INVENTION

1. Field of the Invention

The present invention relates to the technical field of filter devices and, more particularly, to an active and configurable filter device adapted for various specifications.

2. Description of Related Art

Typical receiver architectures can be divided into a single conversion with intermediate frequency (IF), a single conversion with low IF, a single conversion with zero IF, a dual conversion with IF, a dual conversion with low IF, and a dual conversion with zero IF. In the architectures of the single conversion with IF, the dual conversion with IF, and the dual conversion with low IF, an IF filter performs the frequency selection and filtering function. A surface acoustic wave (SAW) filter has the advantages of high quality factor (Q factor), low frequency offset, and low power consumption, but the SAW filter requires a special process and is difficult in integration into a single chip. Thus, a receiver is typically connected with an external SAW filter.

FIG. 1 schematically illustrates a typical receiver with a SAW filter, which converts a radio frequency (RF) signal into an intermediate frequency (IF) signal. The SAW filter 110 is disposed outside the tuner 120. Typically, a SAW filter has very high Q factor and better frequency selectivity, but a higher price makes the entire cost of a tuner significantly high. Also, the SAW filter driver 121 requires few hundreds of mW in power consumption in order to drive the low impedance SAW filter externally connected. Further, the SAW filter itself has very high signal loss, which indicates a reduction in signal to noise ratio (SNR).

For replacing the SAW filter and integrating it into a single chip, an intermediate frequency (IF) filter can be designed as various types such as a resistor-capacitor filter (RC filter), a switch-capacitor filter (SC filter), and a transconductor-capacitor filter (Gm-C filter).

The RC filter is applied only for a KHz-order filter due to the limited bandwidth of an operational amplifier, and not suitable for an IF operation. For the SC filter, the parameters are set based on the capacitance ratio. In a CMOS process, the capacitance ratio can be controlled accurately. In this case, the SC filter can use the capacitance ratio to determine the filter characteristic without being easily affected by the process, but still it is not suitable for a filter over 10 MHz due to the high power consumption and the bandwidth of the operational amplifier.

The Gm-C filter uses one or more transconductance amplifiers and/or capacitors to simulate a resistive and inductive effect. FIG. 2 schematically illustrates a transconductance amplifier simulating the resistive effect in the prior art, where the simulated resistance is

$$\frac{1}{{G}_{m}} ,$$

for Gm indicates the transconductance of the transconductance amplifier 210. FIG. 3 schematically illustrates two transconductance amplifiers and one capacitor which simulate the inductive effect in the prior art, where the simulated inductance is

$$\frac{C}{{G}_{1} \times {G}_{2}} ,$$

for C indicates the capacitance of the capacitor 310, G1 indicates the transconductance of the transconductance amplifier 320, and G2 indicates the transconductance of the transconductance amplifier 330.
For designing a Gm-C filter, the circuit of resistor-inductor-capacitor (RLC) filter has to be designed first. FIG. 4 shows a circuit of a typical RLC filter. In FIG. 4, the resistors can be replaced with the circuit of FIG. 2 while the inductors can be replaced with the circuit of FIG. 3. Therefore, when the Gm-C filters are used to design an IF filter, it is likely to cause the problem that the circuit area is too large. In addition, the coefficients of the Gm-C filters are typically a product of two different components. For example, as cited above, the simulated inductance is obtained by dividing the capacitance of the capacitor 310 by a product of the transconductance of the transconductance amplifiers 320, 330. Further, the error rate for the coefficients of an SC filter is as low as 0.1%, but the error rate for the coefficients of a Gm-C filter in the initial stage is as high as 30%. Therefore, it is desirable to provide an improved filter device to mitigate and/or obviate the aforementioned problems.

### SUMMARY OF THE INVENTION

The object of the present invention is to provide an active and configurable filter device adapted for various specifications, which can be applied in a receiver without using a SAW filter to save the cost and enable the filter to be integrated into a single chip easily thereby requiring only a smaller chip area. Also, the filter device has an adjustable gain, a central frequency and a bandwidth, and the signal to noise ratio (SNR) is increased due to no signal loss and having a positive gain.

To achieve the object, there is provided an active and configurable filter device, which includes: a first filter having a first quality factor for defining a bandwidth and central frequency of the filter device; a second filter connected to the first filter and having a second quality factor for using spectrums of the first filter and second filter to define a low bound frequency and sharpness of the bandwidth of the filter device; and a third filter connected to the second filter and having a third quality factor for using spectrums of the first filter and third filter to define an upper bound frequency and sharpness of the bandwidth of the filter device, wherein the first quality factor has a value in a range of 5 to 15, and the second quality factor and the third quality factor each have a value over 15.

Other objects, advantages, and novel features of the invention will become more apparent from the following detailed description when taken in conjunction with the accompanying drawings.

### BRIEF DESCRIPTION OF THE DRAWINGS

FIG. 1 schematically illustrates a typical tuner with a SAW filter;

FIG. 2 schematically illustrates a transconductance amplifier simulating a resistive effect in the prior art;

FIG. 3 schematically illustrates two transconductance amplifiers and one capacitor which simulate an inductive effect in the prior art;

FIG. 4 is a circuit diagram of a typical RLC filter;

FIG. 5 is a circuit diagram of an active and configurable filter device adapted for various specifications in accordance with an embodiment of the invention;

FIG. 6 schematically illustrates spectrums of a filter device, and the first, the second, and the third filters in accordance with an embodiment of the invention;

FIG. 7 is a circuit diagram of each of the first, the second, and the third filters in accordance with an embodiment of the invention;

FIG. 8 is a circuit diagram of capacitor banks in accordance with an embodiment of the invention;

FIG. 9 schematically illustrates a spectrum simulation of a filter device in accordance with an embodiment of the invention; and

FIG. 10 schematically illustrates spectrums of the first, the second, and the third filters in accordance with an embodiment of the invention.

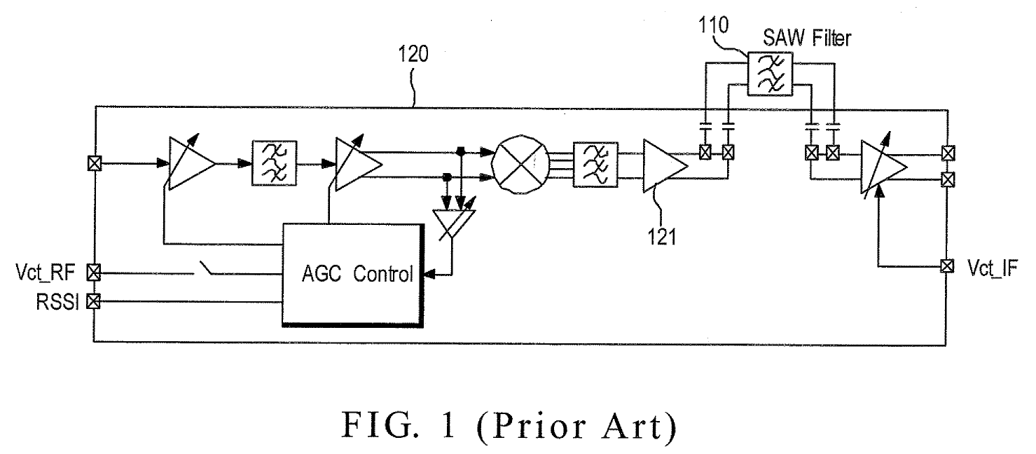

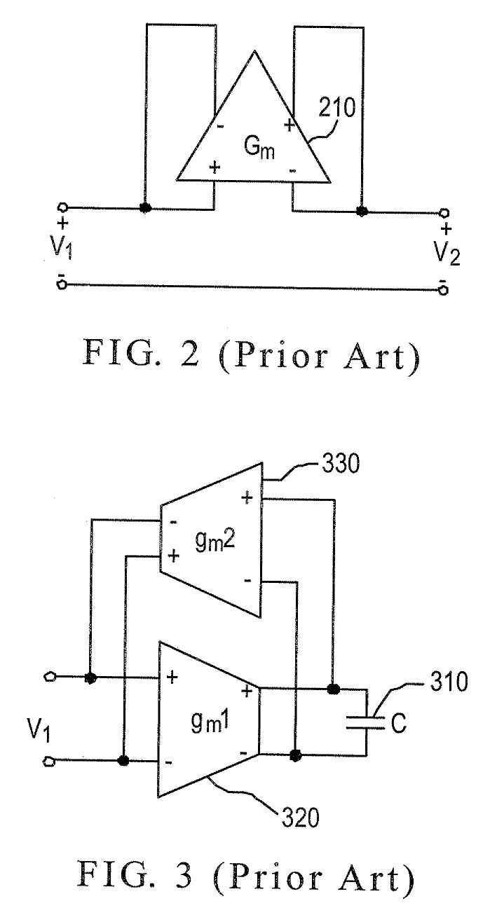

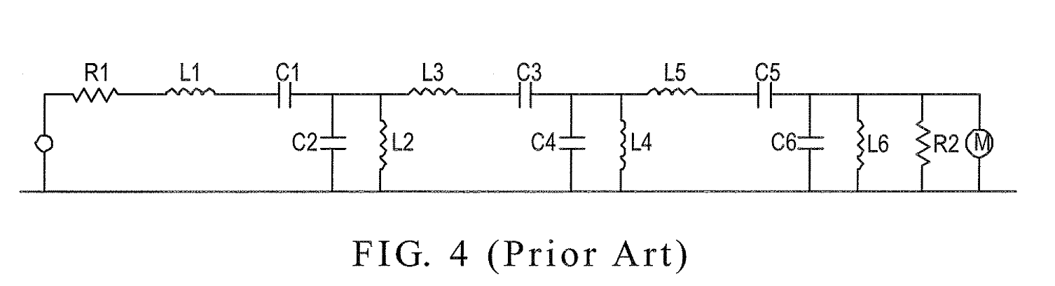

### DETAILED DESCRIPTION OF THE PREFERRED EMBODIMENT

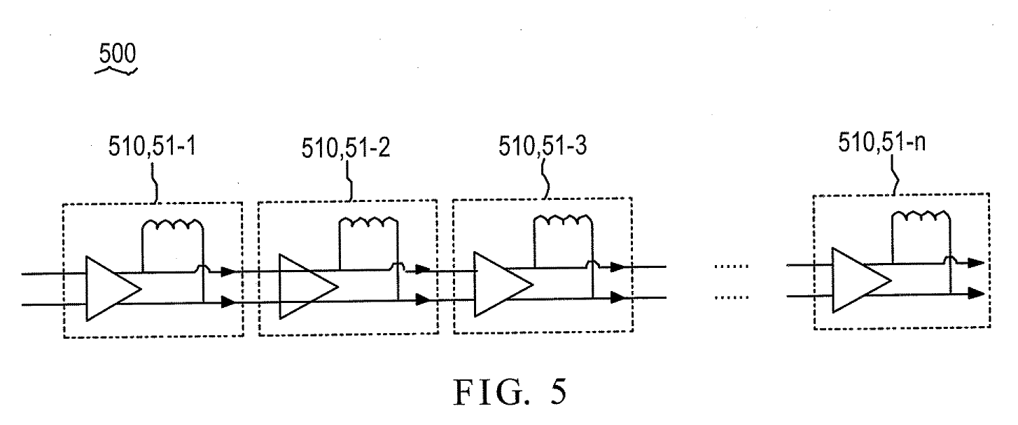

The present invention relates to an active and configurable filter device adapted for various specifications, which can be applied in a receiver or an analog to digital converter (ADC). FIG. 5 is a circuit of an active and configurable filter device 500 adapted for various specifications in accordance with an embodiment of the invention. The filter device 500 is formed by connecting an odd or even number of filters 510 in series. For example, three, four, or even seven filters 510 are connected in series to form the filter device 500. For convenient description, this embodiment is given by connecting three filters 510 in series as an example, but not limited to it. The other odd number of filters connected in series can be embodied by those skilled in the art.

The active and configurable filter device 500 includes a first filter 51-1, a second filter 51-2, and a third filter 51-3.

The first filter 51-1 has a first quality factor Q1 with a relative low value to roughly define the bandwidth BW and central frequency fc of the filter device 500. The second filter 51-2 is connected to the first filter 51-1 and has a second quality factor Q2 with a relative high value. The spectrums of the first and second filters 51-1, 51-2 precisely define a lower bound frequency f_{L} and sharpness of the bandwidth of the filter device 500. The third filter 51-3 is connected to the second filter 51-2 and has a third quality factor Q3 with a relative high value in order to precisely define an upper bound frequency f_{H} and sharpness of the bandwidth of the filter device 500. The first quality factor Q1 has a value in a range of 5 to 15, and the second quality factor Q2 and the third quality factor Q3 each have a value over 15.

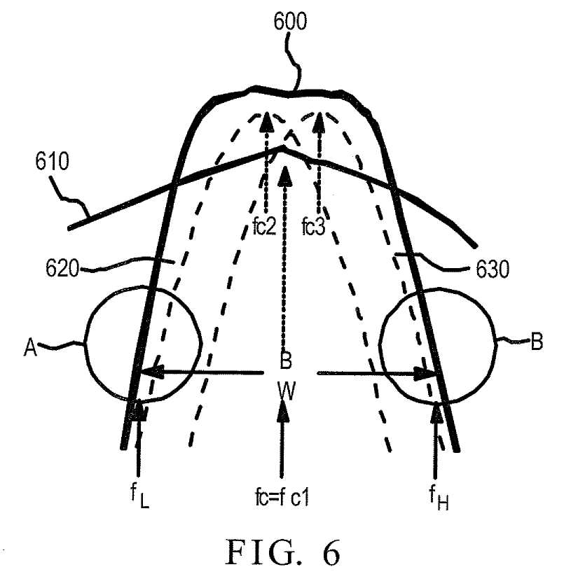

FIG. 6 schematically illustrates the spectrums of the filter device 500, the first filter 51-1, the second filter 51-2 and the third filter 51-3 in accordance with an embodiment of the invention. As shown in FIG. 6, line 610 indicates the spectrum of the first filter 51-1, which has a larger bandwidth due to the lower value, about 5-15, of the first quality factor Q1. Since the first filter 51-1 of the filter device 500 is designed symmetrically, the central frequency fc1 of the first filter 51-1 can be used as the central frequency fc of the filter device 500.

Similarly, line 620 indicates the spectrum of the second filter 51-2, line 630 indicates the spectrum of the third filter 51-3, and line 600 indicates the spectrum of the filter device 500. The central frequency fc2 of the second filter 51-2 is smaller than the central frequency fc1 of the first filer 51-1, and the central frequency fc1 of the first filter 51-1 is smaller than the central frequency fc2 of the third filter 51-3. Since the second quality factor Q2 and the third quality factor Q3 each have a value over 15, the bandwidths are smaller with respect to that of the first filter 51-1.

As shown in FIG. 6, the spectrums of the first and second filters 51-1, 51-2 define a lower bound frequency f_{L} and sharpness of the bandwidth of the filter device 500, as denoted by circle A. Similarly, the spectrums of the first and third filters 51-1, 51-3 define an upper bound frequency f_{H} and sharpness of the bandwidth of the filter device 500, as denoted by circle B in FIG. 6.

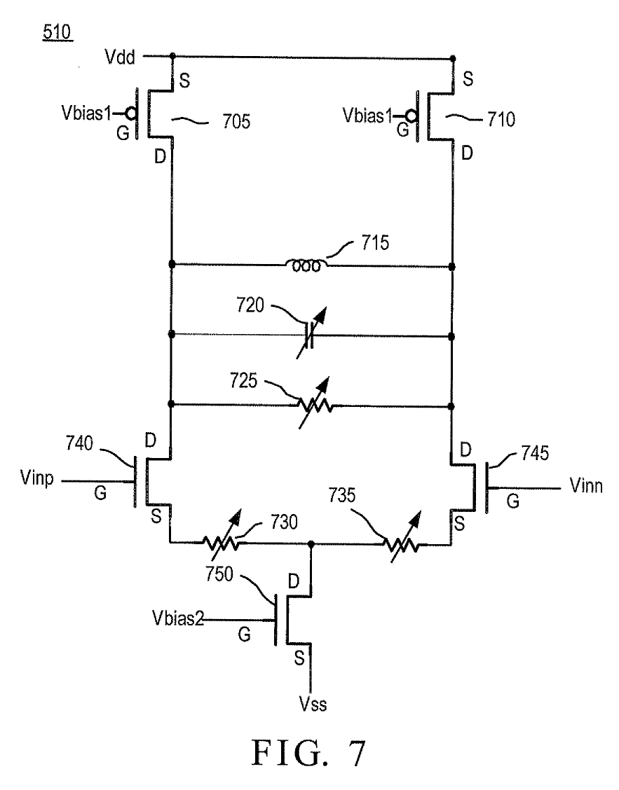

FIG. 7 is a circuit of each of the first, the second, and the third filters 51-1, 51-2, and 51-3 in accordance with an embodiment of the invention. It is known from FIG. 7 that the central frequencies and gains of the first, the second, and the third filters 51-1, 51-2, and 51-3 are adjustable.

As shown in FIG. 7, each of the first, the second, and the third filters 51-1, 51-2, and 51-3 is comprised of a first PMOS transistor 705, a second PMOS transistor 710, a first inductor 715, a first variable capacitor 720, a first variable resistor 725, a second variable resistor 730, a third variable resistor 735, a first NMOS transistor 740, a second NMOS transistor 745, and a third NMOS transistor 750.

The sources of the first and the second PMOS transistors 705 and 710 are connected to a high voltage Vdd. The gates of the first and the second PMOS transistors 705 and 710 are connected to a first bias voltage Vbias1.

The drain of the first PMOS transistor 705 is connected to one end of the first inductor 715, one end of the first variable capacitor 720, one end of the first variable resistor 725, and a drain of the first NMOS transistor 740. The drain of the second PMOS transistor 710 is connected to the other end of the first inductor 715, the other end of the first variable capacitor 720, the other end of the first variable resistor 725, and a drain of the second NMOS transistor 745.

The gates of the first and the second NMOS transistors 740 and 745 receive a differential voltage (Vinp, Vinn). The source of the first NMOS transistor 740 is connected to one end of the second variable resistor 730, and the source of the second NMOS transistor 745 is connected to one end of the third variable resistor 735. The other end of the second variable resistor 730 is connected to the other end of the third variable resistor 735 and a drain of the third NMOS transistor 750. The gate of the third NMOS transistor 750 is connected to a second bias voltage Vbias2, and the source of the third NMOS transistor 750 is connected to a low voltage Vss.

For each of the first, the second, and the third filters 51-1, 51-2, and 51-3, the first PMOS transistor 705, the second PMOS transistor 710, the first variable capacitor 720, the first variable resistor 725, the second variable resistor 730, the third variable resistor 735, the first NMOS transistor 740, the second NMOS transistor 745, and third NMOS transistor 750 are integrated into one integrated circuit (IC). The first inductor 715 can be disposed either outside or inside the IC, depending on the processing variation of the inductor.

It is noted that, in this embodiment, each of the first, the second, and the third filters 51-1, 51-2, and 51-3 has the same structure, but the values of the first variable capacitor 720, the first variable resistor 725, the second variable resistor 730, and the third variable resistor 735 are different in the filters 51-1, 51-2, and 51-3. Similarly, the first inductor 715 may have a different inductance with respect to each filter, so as to adjust the gains, central frequencies and bandwidths of the first, the second, and the third filters 51-1, 51-2, and 51-3.

For adjusting the gain of the filter device 500, the values of the second and third variable resistors 730, 735 of the filters 51-1, 52-2, 53-3 are concurrently adjusted to become large, so as to make the entire gain of the filter device 500 become small. Conversely, the entire gain of the filter device 500 becomes large when the values are adjusted to become small.

For adjusting the central frequency of the filter device 500 without changing the bandwidth, the first variable capacitors 720 of the filters 51-1, 51-2, 51-3 are concurrently adjusted so as to adjust the central frequency of the filter device 500. Namely, when the first variable capacitors 720 of the filters 51-1, 51-2, 51-3 are adjusted to become small, the central frequency fc of the filter device 500 shifts to a high frequency. Conversely, when the first variable capacitors 720 of the filters 1, 2, 3 are adjusted to become large, the central frequency fc of the filter device 500 shifts to a low frequency.

For adjusting the bandwidth of the filter device 500 without changing the central frequency, the first variable capacitor 720 of the second filter 51-2 is adjusted to become small in order to shift the central frequency fc2 of the second filter 51-2 to a high frequency, and the first variable capacitor 720 of the third filter 51-3 is adjusted to become large in order to shift the central frequency fc3 of the third filter 51-3 to a low frequency, thereby generating the entire effect of reducing the bandwidth of the filter device 500 without changing the central frequency. Conversely, the first variable capacitor 720 of the second filter 51-2 is adjusted to become large in order to shift the central frequency fc2 of the second filter 51-2 to a low frequency, and the first variable capacitor 720 of the third filter 51-3 is adjusted to become small in order to shift the central frequency fc3 of the third filter 51-3 to a high frequency, thereby generating the entire effect of increasing the bandwidth of the filter device 500 without changing the central frequency.

As shown in FIG. 7, since each of the filters 51-1, 51-2, and 51-3 is designed symmetrically, the second and the third variable resistors 730 and 735 have the same resistance.

The first, the second, and the third filters 51-1, 51-2, and 51-3 have a structure regarded as source degeneration. Accordingly, the gain of the first filter 51-1 is a resistance ratio of its first variable resistor 725 to second variable resistor 730, the gain of the second filter 51-2 is a resistance ratio of its first variable resistor 725 to second variable resistor 730, and the gain of the third filter 51-3 is a resistance ratio of its first variable resistor 725 to second variable resistor 730.

The bandwidth BW1 and central frequency fc1 of the first filter 51-1 is determined from the first inductor 715, the first variable capacitor 720, and the first variable resistor 725 of the first filter 51-1. The bandwidth BW2 and central frequency fc2 of the second filter 51-2 is determined from the first inductor 715, the first variable capacitor 720, and the first variable resistor 725 of the second filter 51-2. The bandwidth BW3 and central frequency fc3 of the third filter 51-3 is determined from the first inductor 715, the first variable capacitor 720, and the first variable resistor 725 of the third filter 51-3.

In each of the first filter 51-1, the second filter 51-2, and the third filter 51-3, the first variable capacitor 720 is a capacitor bank, and the first variable resistor 725, the second variable resistor 730, and the third variable resistor 735 are a resistor bank.

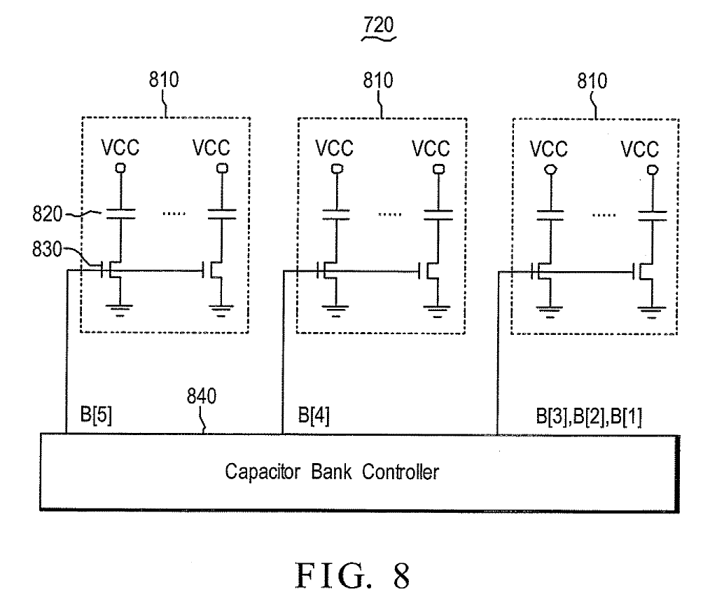

FIG. 8 is a schematic view of a capacitor bank in accordance with an embodiment of the invention. As shown in FIG. 8, the capacitor bank includes a plurality of capacitor selection devices 810 and a capacitor bank controller 840. Each capacitor selection device 810 has N capacitors 820 and N switches 830, where N is an integer greater than one.

The N switches 830 of each capacitor selection device 810 are each an NMOS transistor with a gate connected to the capacitor bank controller 840.

In this embodiment, the capacitors of each capacitor selection device 810 can be a base-emitter junction capacitor, a MOSFET capacitor, or a poly-poly capacitor. In other embodiments, the capacitors of each capacitor selection device 810 can be a metal-insulator-metal (MIM) capacitor.

As shown in FIG. 8, the capacitors of the capacitor bank 720 can be expressed as follows:

(C_{Paracitic}+B[1]×C_{B1}+B[2]×C_{B2}+B[3]×C_{B3}+B[4]×C_{B4}+B[5]×C_{B5}),

where C_{Paracitic} indicates parasitic capacitance, C_{B1}, C_{B2}, C_{B3}, C_{B4} and C_{B5} are the capacitances of the capacitor selection devices 810, and B[1], B[2], B[3], B[4], or B[5], represented by B[i], indicates a control signal outputted from the capacitor bank controller 840 to the capacitor bank. C_{B5} is the capacitance of the capacitor selection device 810 corresponding to the control signal B[5]. When B[i]=0, it indicates that the corresponding NMOS transistor is turned off, and the capacitor is at a floating state, without the capacitance effect. When B[i]=1, it indicates that the corresponding NMOS transistor is turned on, and the capacitor is grounded to generate the capacitance effect. The capacitor bank controller 840 can output a control signal to adjust the capacitance of the first variable capacitor 720. As shown in FIG. 8, the first, the second, and the third variable resistors 725, 730, and 735 can be operated in a similar manner.

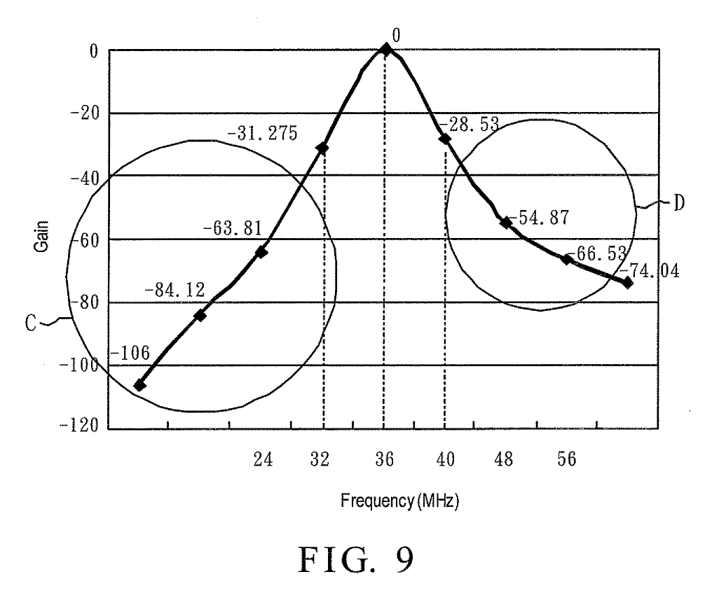

FIG. 9 schematically illustrates a spectrum simulation of the filter device 500 in accordance with an embodiment of the invention. The filter device 500 is comprised of three filters. The gain does not decrease at the stop band of the spectrum of a typical SAW filter, which has noises with a higher amplitude at the stop band, resulting in interfering the receiving signal. By contrast, as shown in FIG. 9, the gains at the stop bands indicated by circles C, D in the invention remain in reduction, so as to prevent the receiving signal from being interfered by noises of the stop bands.

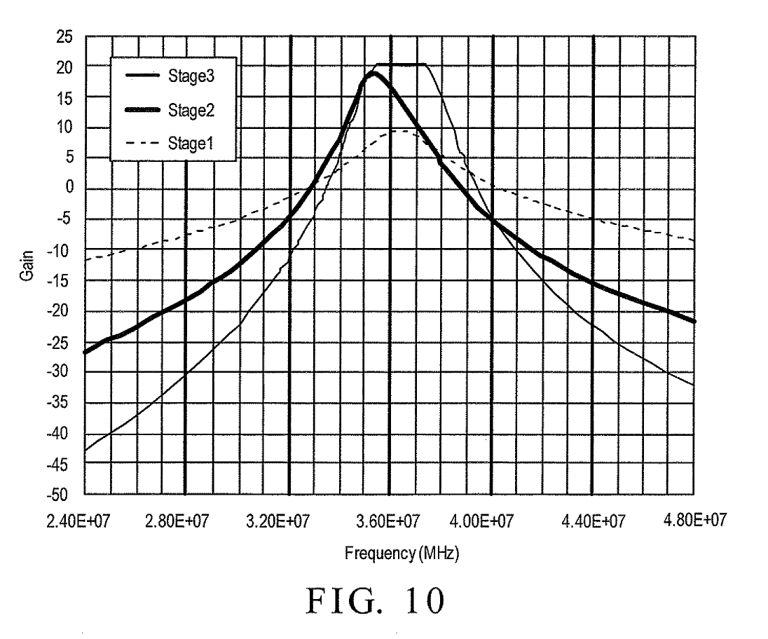

FIG. 10 schematically illustrates spectrums of the first, the second, and the third filters in accordance with an embodiment of the invention. As shown in FIG. 10, the spectrum of the first filter 51-1 is indicated by a dotted line and has a larger bandwidth, the spectrum of the first and the second filters 51-1, 51-2 is indicated by a bold line, and the spectrum of the first, the second, and the third filters 51-1, 51-2, 51-3 is indicated by a solid line. Since the gain of each filter can be adjusted, the filter device 500 comprised of the first filter 51-1, the second filter 51-2, and the third filter 51-3 has a gain of 20 dB at the frequency of 36 MHz, a gain of −5 dB at the frequency of 40 MHz, and a gain of −12 dB at the frequency of 32 MHz.

In view of the foregoing, it is known that the active and configurable filter device 500 of the present invention has the advantages as follows:

1. There is no insertion loss, and the gain is adjustable with low noise.

2. The parameters of the filter device are adjustable, wherein the parameters include: adjustable gain; adjustable bandwidth; and adjustable central frequency.

3. The filter device can be integrated into a single chip easily and requires an area smaller than the Gm-C filter in the prior art.

4. The SAW filter can be eliminated, so as to reduce the cost.

Since the invention has the aforementioned advantages, it can be adapted for any wireless receiver system, an analog audio system, and an analog video system.

Although the present invention has been explained in relation to its preferred embodiment, it is to be understood that many other possible modifications and variations can be made without departing from the spirit and scope of the invention as hereinafter claimed.

What is claimed is:

1. An active and configurable filter device, comprising:
a first filter having a first quality factor for defining a bandwidth and central frequency of the filter device;
a second filter connected to the first filter and having a second quality factor for using spectrums of the first filter and second filter to define a low bound frequency and sharpness of the bandwidth of the filter device; and
a third filter connected to the second filter and having a third quality factor for using spectrums of the first filter and third filter to define an upper bound frequency and sharpness of the bandwidth of the filter device,
wherein the first quality factor has a value in a range of 5 to 15, and the second quality factor and the third quality factor each have a value over 15.

2. The active and configurable filter device as claimed in claim 1, wherein each of the first filter, the second filter, and the third filter is comprised of a first PMOS transistor, a second PMOS transistor, a first inductor, a first variable capacitor, a first variable resistor, a second variable resistor, a third variable resistor, a first NMOS transistor, a second NMOS transistor, and a third NMOS transistor.

3. The active and configurable filter device as claimed in claim 2, wherein for each of the first, the second, and the third filters, the first and the second PMOS transistors each have a source connected to a high voltage and a gate connected to a first bias voltage; the first PMOS transistor has a drain connected to one end of the first inductor, one end of the first variable capacitor, one end of the first variable resistor, and a drain of the first NMOS transistor; the second PMOS transistor has a drain connected to the other end of the first inductor, the other end of the first variable capacitor, the other end of the first variable resistor, and a drain of the second NMOS transistor; gates of the first and the second NMOS transistors receive a differential voltage; the first NMOS transistor has a source connected to one end of the second variable resistor; the second NMOS transistor has a source connected to one end of the third variable resistor; the second variable resistor has the other end connected to the other end of the third variable resistor and a drain of the third NMOS transistor; the third NMOS transistor has a gate connected to a second bias voltage and a source connected to a low voltage.

4. The active and configurable filter device as claimed in claim 3, wherein for each of the first, the second, and the third filters, the first PMOS transistor, the second PMOS transistor, the first variable capacitor, the first variable resistor, the second variable resistor, the third variable resistor, the first NMOS transistor, the second NMOS transistor, and the third NMOS transistor are integrated into an integrated circuit.

5. The active and configurable filter device as claimed in claim 4, wherein for each of the first, the second, and the third filters, the second and the third variable resistors have same resistance.

6. The active and configurable filter device as claimed in claim 5, wherein the first filter has a gain equal to a resistance ratio of the first variable resistor to second variable resistor of the first filter, the second filter has a gain equal to a resistance ratio of the first variable resistor to second variable resistor of the second filter, and the third filter has a gain equal to a resistance ratio of the first variable resistor to second variable resistor of the third filter.

7. The active and configurable filter device as claimed in claim 6, wherein the bandwidth and central frequency of the first filter is determined from the first inductor, the first variable capacitor, and the first variable resistor of the first filter, the bandwidth and central frequency of the second filter is determined from the first inductor, the first variable capacitor, and the first variable resistor of the second filter, and the bandwidth and central frequency of the third filter is determined from the first inductor, the first variable capacitor, and the first variable resistor of the third filter.

8. The active and configurable filter device as claimed in claim 7, wherein the central frequency of the second filter is smaller than that of the first filter, and the central frequency of the first filter is smaller than that of the third filter.

9. The active and configurable filter device as claimed in claim 8, wherein the first variable capacitor in each of the first, the second, and the third filters is a capacitor bank.

10. The active and configurable filter device as claimed in claim 9, wherein the first, the second, and the third variable resistors in each of the first, the second, and the third filters are a resistor bank.

11. The active and configurable filter device as claimed in claim 10, wherein the capacitor bank in each of the first, the second, the third filters comprises a plurality of capacitor selection devices, and the capacitor selection devices each have N capacitors and N switches, where N is an integer greater than one.

12. The active and configurable filter device as claimed in claim 11, wherein the switches are each an NMOS transistor.

13. The active and configurable filter device as claimed in claim 12, wherein the capacitors of the capacitor selection devices are metal-insulator-metal (MIM) capacitors.

14. The active and configurable filter device as claimed in claim 13, wherein the capacitors of the capacitor bank are expressed as:
(C_{Paracitic}+B[1]×C_{B1}+B[2]×C_{B2}+B[3]×C_{B3}+B[4]×C_{B4}+B[5]×C_{B5}),
where C_{Paracitic} indicates parasitic and stray capacitance, C_{B1}, C_{B2}, C_{B3}, C_{B4}, and C_{B5} are capacitances of the capacitor selection devices, and B[1], B[2], B[3], B[4] and B[5] indicate a control signal outputted from a capacitor bank controller to the capacitor bank.
